(19) United States
(12) Patent Application Publication
(10) Pub. No.: US 2011/0309887 A1
(43) Pub. Date: Dec. 22, 2011

(54) ATOMIC OSCILLATOR

(75) Inventors: Yoshiyuki MAKI, Hino (JP); Hiroyuki YOSHIDA, Hino (JP); Yoshiaki TANAKA, Yokohama (JP)

(73) Assignee: SEIKO EPSON CORPORATION, Tokyo (JP)

(21) Appl. No.: 13/162,966

(22) Filed: Jun. 17, 2011

(30) Foreign Application Priority Data
Jun. 21, 2010 (JP) 2010-140230

(51) Int. Cl. H03B 17/00

(52) U.S. Cl. 331/94.1

(57) ABSTRACT

An atomic oscillator includes a cell containing a mixture gas of alkali metal atoms and isotopes of the alkali metal atoms, a light source that has coherency and irradiates the gas with lights including a first resonant light pair having two different frequency components for one center frequency and a second resonant light pair, a photo detector that generates a detection signal corresponding to intensity of light passing through the gas, and a frequency control part that controls, based on the detection signal, frequencies of the first resonant light pair to cause an electromagnetically induced transparency phenomenon to occur in the alkali metal atom and controls frequencies of the second resonant light pair to cause the electromagnetically induced transparency phenomenon to occur in the isotope of the alkali metal atom.

### BACKGROUND

1. Technical Field

The present invention relates to a method of controlling a light source of an atomic oscillator, and more particularly to a method of controlling a light source of an atomic oscillator to stabilize absorption and capture by absorption gain varying of the atomic oscillator.

2. Related Art

An atomic oscillator of an EIT (Electromagnetically Induced Transparency) system (also called a CPT (Coherent Population Trapping) system) is an oscillator using a phenomenon (EIT phenomenon) in which when two resonant lights different in wavelength are simultaneously irradiated to an alkali metal atom, the absorption of the two resonant lights is stopped. Accordingly, it is important to stably obtain the EIT phenomenon.

It is known that the interaction mechanism between the alkali metal atom and the two resonant lights can be explained in a Λ-type three-level system model as shown in FIG. 7A. The alkali metal atom has two ground levels, and when a first resonant light 31 having a wavelength (frequency f1) corresponding to an energy difference between a first ground level 33 and an excited level 30 or a second resonant light 32 having a wavelength (frequency 2) corresponding to an energy difference between a second ground level 34 and the excited level 30 is individually irradiated to the alkali metal atom, light absorption occurs as is well known. However, when the first resonant light 31 and the second resonant light 32, whose frequency difference f1-f2 is accurately coincident with a frequency (transition frequency) corresponding to an energy difference ΔE12 between the first ground level 33 and the second ground level 34, are simultaneously irradiated to the alkali metal atom, a superimposed state of the two ground levels, that is, a quantum interference state occurs, the excitation to the excited level 30 is stopped, and the transparency phenomenon (EIT phenomenon) occurs in which the first resonant light 31 and the second resonant light 32 pass through the alkali metal atom. An oscillator with high accuracy can be formed by controlling and detecting the abrupt change of the light absorption behavior when the frequency difference f1-f2 between the first resonant light 31 and the second resonant light 32 shifts from the frequency corresponding to the energy difference ΔE12 between the first ground level 33 and the second ground level 34.

In the related art atomic oscillator of the CPT system, a drive current of a frequency f₀(=v/λ₀: v is the light speed, λ₀ is the center wavelength of laser light) generated by a current drive circuit is modulated by a modulation frequency fm1 which is ½ of the frequency (transition frequency) corresponding to the energy difference ΔE12 between the first ground level 33 and the second ground level 34, so that the first resonant light 31 of the frequency f₁=f₀+fₘ₁ and the second resonant light 32 of the frequency f₂=f₀−fₘ₁ are generated in the semiconductor laser (FIG. 7B), and the EIT phenomenon is caused to occur in a gaseous alkali metal atom included in an atomic cell. In this atomic oscillator, the oscillation frequency of a voltage controlled crystal oscillator (VCXO) is controlled so that the detection amount of light passing through the atomic cell becomes maximum. The oscillation frequency is multiplied by a PLL at a multiplication ratio N/R (both N and R are positive integers), and the signal of the modulation frequency fm1 which is ½ of the frequency corresponding to ΔE12 is generated. According to the structure as stated above, since the voltage controlled crystal oscillator (VCXO) continues the oscillation operation very stably, the oscillation signal having very high frequency stability can be generated.

As related art, U.S. Pat. No. 6,320,472 (patent document 1) discloses a circuit structure in which a bias current to a semiconductor laser is modulated with a low frequency signal and the absorption is stabilized (see FIG. 8). According to this, a lock-in amplifier (synchronization detector circuit) is used in order to stabilize the center wavelength (carrier frequency) of the semiconductor laser light, and the output signal of the lock-in amplifier is fed back in analog form, so that the center wavelength of the semiconductor laser is controlled. That is, the lock-in amplifier functions as a narrow band filter, and only a desired component necessary for the feedback control is detected, so that the highly accurate frequency control becomes possible.

However, in the related art disclosed in patent document 1, as shown in FIG. 7B, the drive current of the frequency f₀(=v/λ₀: v is the light speed, λ₀ is the center wavelength of the laser light) generated by the current drive circuit is modulated by the modulation frequency fₘ₁ which is ½ of the frequency corresponding to the energy difference ΔE12 between the first ground level 33 and the second ground level 34. As a result, the first resonant light 31 of the frequency f₁=f₀+fₘ₁ and the second resonant light 32 of the frequency f₂=f₀−fₘ₁ are generated in the semiconductor laser, and the EIT phenomenon is caused to occur in the gaseous alkali metal atom included in the atomic cell. In the EIT phenomenon, as the number of alkali metal atoms included in the cell becomes large, the number of atoms contributing to the EIT phenomenon becomes large, and the level of the light detected by the light detector becomes large. However, when the number of alkali metal atoms included in the cell is decreased because of recent request for miniaturization and reduction in power consumption, the number of atoms contribution to the EIT phenomenon becomes small, and there is a problem that the level of the detected light decreases, and S/N degrades.

### SUMMARY

An advantage of some aspects of the invention is to provide an atomic oscillator which uses the fact that an alkali metal atom has an isotope, and in which the level of light detected by a light detector is raised and S/N is improved by irradiating a mixture gas of an alkali metal atom and an isotope of the alkali metal atom with plural lights including a first resonant light pair having two frequency components different in frequency and a second resonant light pair having two frequency components different in frequency.

### Application Example 1

This application example of the invention is directed to an atomic oscillator that uses an electromagnetically induced transparency phenomenon generated by irradiating a resonant light pair to an alkali metal atom, and includes a gas, a light source, a photo detector and a frequency control part. The gas includes a mixture of the alkali metal atom and an isotope of the alkali metal atom. The light source has coherency and irradiates the gas with plural lights including a first resonant light pair having two frequency components different in frequency and a second resonant light pair having two frequency components different in frequency. The photo detector generates a detection signal corresponding to the intensity of light passing through the gas. The frequency control part controls, based on the detection signal, a frequency difference between the two frequency components of the first resonant light pair to cause the electromagnetically induced transparency phenomenon to occur in the alkali metal atom and controls a frequency difference between the two frequency components of the second resonant light pair to cause the electromagnetically induced transparency phenomenon to occur in the isotope of the alkali metal atom.

In order to generate at least four resonant lights (two resonant light pairs), it is conceivable that a resonant light emitted from a coherent light source is modulated to generate side bands, and the frequency spectrum thereof is used. The modulation frequency of the resonant light is required to be equal to the frequency which is ½ of the frequency corresponding to ΔE12. Then, according to the application example of the invention, the gas including the mixture of the alkali metal atom and the isotope of the alkali metal atom is prepared, and the frequency control part controls the frequency difference of each of the two resonant light pairs. By this, the resonant lights having the four frequency spectra keeping the frequency which is ½ of the frequency corresponding to ΔE12 can be generated from the resonant light emitted from the coherent light source.

### Application Example 2

This application example of the invention is directed to the atomic oscillator of the above application example, wherein the alkali metal atom is rubidium having a mass number of 85, and the isotope of the alkali metal atom is rubidium having a mass number of 87.

It is known that rubidium has 24 kinds of isotopes. Naturally existing rubidium includes two kinds of isotopes, that is, a stable isotope 85Rb at a natural existing ratio of 72.2% and a radioactive isotope 87Rb at 27.8%. That is, with respect to the center wavelength, the D1 line of 795 nm and the D2 line of 780 nm are common to 85Rb and 87Rb. However, the transition frequency of 85Rb is 6.8 GHz, the transition frequency of 87Rb is 3.0 GHz, and the two kinds of transition frequencies are obtained. By this, one laser light can generate two kinds of side bands, and the number of atoms contributing to the EIT phenomenon can be increased.

### Application Example 3

This application example of the invention is directed to the atomic oscillator of the above application example, wherein the frequency control part includes a phase modulation part to phase modulate an output signal of a voltage controlled crystal oscillator by a specified frequency, a first frequency multiplying part to multiply the signal phase-modulated by the phase modulation part to a frequency equal to ½ of a transition frequency of the alkali metal atom, a second frequency multiplying part to multiply the frequency of the signal phase-modulated by the phase modulation part to a frequency equal to ½ of a transition frequency of the isotope of the alkali metal atom, and a mixer to mix the signal multiplied by the first frequency multiplying part and the signal multiplied by the second frequency multiplying part.

Another feature of the atomic oscillator according to the application example of the invention is the structure of the frequency control part. That is, in order to control two kinds of transition frequencies, there are provided the first frequency multiplying part to multiply the signal phase-modulated by the phase modulation part to the frequency equal to ½ of the transition frequency of the first resonant light pair, and the second frequency multiplying part to multiply the frequency of the signal phase-modulated by the phase modulation part to the frequency equal to ½ of the transition frequency of the second resonant light pair. The mixer to mix the output signals of the first and the second frequency multiplying parts is required. By this, the transition frequencies of the alkali metal atom and the isotope thereof are combined into one, and the light source can be excited.

### Application Example 4

This application example of the invention is directed to the atomic oscillator of the above application example, wherein each of the first frequency multiplying part and the second frequency multiplying part includes the phase modulation part, and one of the phase modulation parts includes a phase shifter to shift a phase.

The phase modulation part is commonly used and the two frequency multiplying parts can be driven. However, there is a possibility that the mutual phases are shifted by a variation in parts. Then, when this phenomenon occurs, it is necessary to shift a phase to perform phase alignment. According to the application example of the invention, one of the phase modulation parts includes the phase shifter to shift the phase. By this, synchronous detection can be accurately and quickly performed.

### Application Example 5

This application example of the invention is directed to the above application example, wherein each of the first frequency multiplying part and the second frequency multiplying part includes the phase modulation part, and one of the phase modulation parts includes an amplitude adjuster to adjust an amplitude of a signal.

The output levels of the two frequency multiplying parts influence the inclination of an error voltage after detection. Accordingly, it is ideally preferable that the output levels of the two frequency multiplying parts are equal to each other. Then, according to the application example of the invention, one of the phase modulation parts includes the amplitude adjuster to adjust the amplitude. By this, the synchronous detection can be accurately and quickly performed.

### Application Example 6

This application example of the invention is directed to the atomic oscillator of the above application example, wherein the light source includes an electro-optical modulator (EOM).

The electro-optical modulator is required in order to modulate light. However, when the number of frequency spectra is increased, the number of electro-optical modulators must be increased by that, and there is a problem that the cost increases, and the number of parts increases. According to the application example of the invention, the output signal of the mixer is inputted as a modulation signal to one electro-optical modulator, and the light emitted from the light source is modulated. By this, the number of electro-optical modulators is made minimum, and the number of parts can be reduced.

### BRIEF DESCRIPTION OF THE DRAWINGS

The invention will be described with reference to the accompanying drawings, wherein like numbers reference like elements.

FIGS. 1A to 1D are views for explaining the basic operation of an EIT phenomenon.

FIGS. 2A to 2C are views for explaining the basic principle of the invention.

FIG. 3 is a block diagram showing a structure of an atomic oscillator of a first embodiment of the invention.

FIG. 4 is a block diagram showing a structure of an atomic oscillator of a second embodiment of the invention.

FIG. 5 is a block diagram showing a structure of an atomic oscillator of a third embodiment of the invention.

FIG. 6 is a block diagram showing a structure of an atomic oscillator of a fourth embodiment of the invention.

FIGS. 7A and 7B are views for explaining an interaction mechanism between an alkali metal atom and two resonant lights.

FIG. 8 is a view showing a circuit structure of an atomic oscillator disclosed in patent document 1.

### DESCRIPTION OF EXEMPLARY EMBODIMENTS

Hereinafter, embodiments of the invention will be described in detail with reference to the drawings. However, components, kinds, combinations, shapes, relative arrangements and the like described in the embodiments are not intended to limit the scope of the invention unless otherwise described, but are merely exemplary.

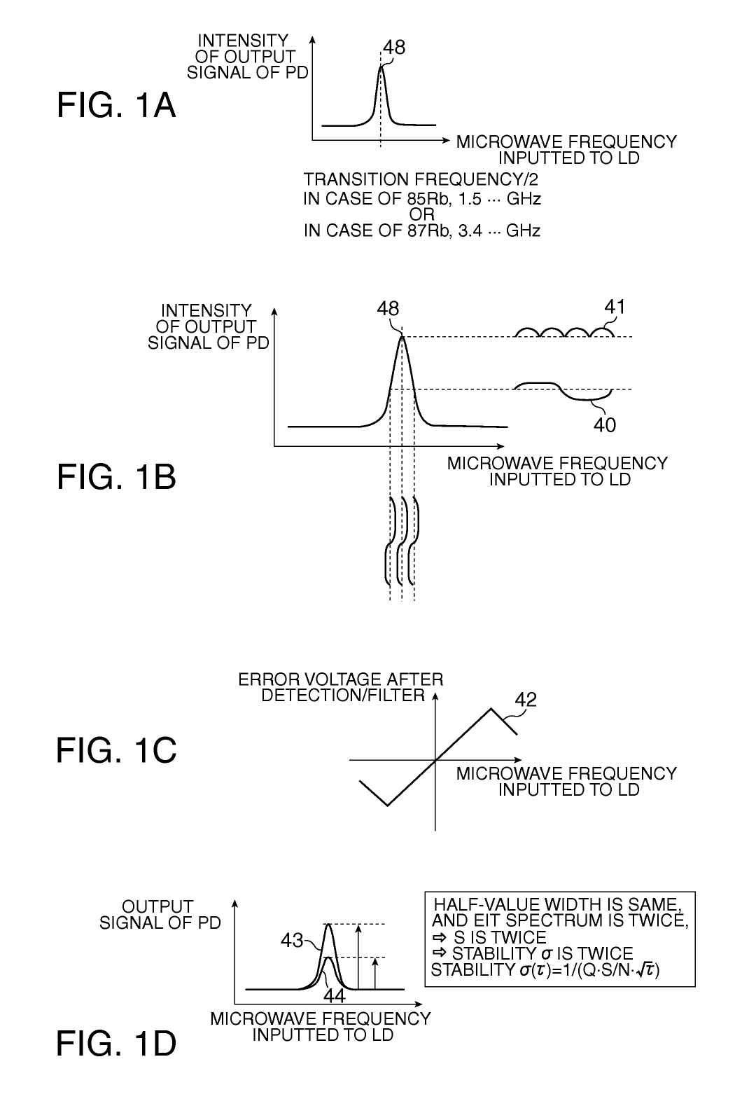

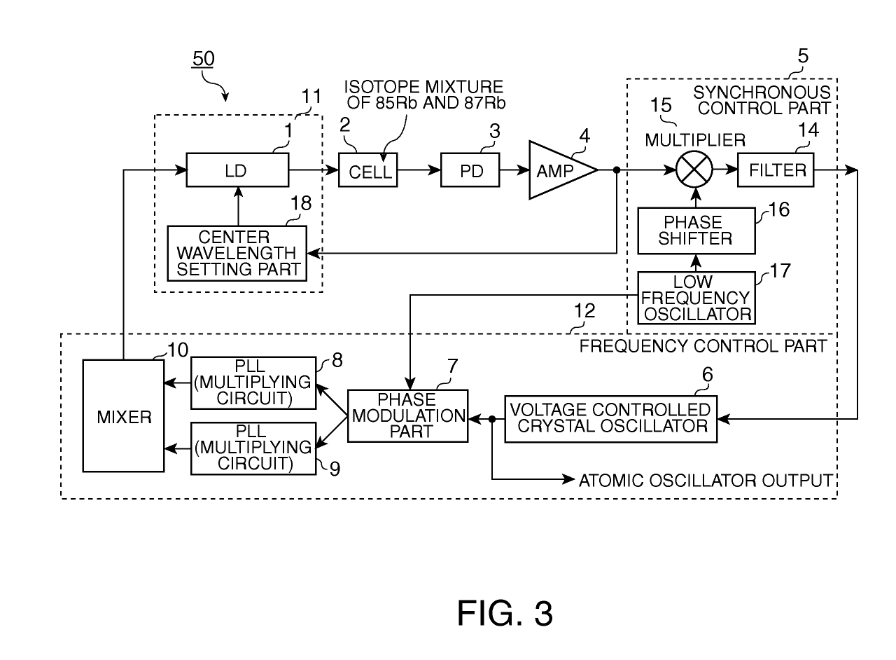

FIGS. 1A to 1D are views for explaining the basic operation of an EIT phenomenon. First, when a power source of an apparatus is turned ON, a center wavelength setting part 18 sets the center wavelength of a light source (LD) 1 so that the output of a photo detector (PD) 3 of FIG. 3 becomes maximum (see FIG. 1A). When an EIT signal 48 is enlarged, the signal is as shown in FIG. 1B. That is, in the case of an unlock state, a waveform 40 is in a state where the center frequency of phase modulation is shifted from a peak of the EIT signal 48, and the output of an amplifier (AMP) 4 pulsates at a frequency of 111 Hz (waveform 40). In an unlock (non-synchronization) state, since the center frequencies of PLL 8 and 9 (first and second frequency multiplying parts) are not locked to ½ of the transition frequency, only a component (111 Hz) of a low frequency oscillator 17 is generated in the output of the AMP 4. Then, feedback control is performed so that a double component (222 Hz) of the low frequency oscillator 17 (111 Hz) becomes maximum in the output of the AMP 4, and like a waveform 41 of FIG. 1B, a lock is accurately performed so that the frequency of the output signal of the light source part 11 becomes equal to ½ of the transition frequency (frequency corresponding to ΔE12). That is, the center frequency of the phase modulation is coincident with the peak of the EIT signal 48. At this time, a synchronous control voltage 42 as shown in FIG. 1C is generated as a synchronous control output signal. The feedback control of a voltage controlled crystal oscillator 6 is performed so that the synchronous control voltage 42 becomes 0 V, and the center frequencies of the PLL 8 and 9 (the first and the second frequency multiplying parts) are accurately locked to ½ of the transition frequency. FIG. 1D is a view for explaining the stability of the frequency, and the stability δ(τ) is expressed by δ(τ)=1/(Q·S/N·√τ). That is, with respect to the waveforms 43 and 44 having the same half-value width, S of the waveform 43 becomes twice the waveform 44, and consequently, the stability t becomes twice.

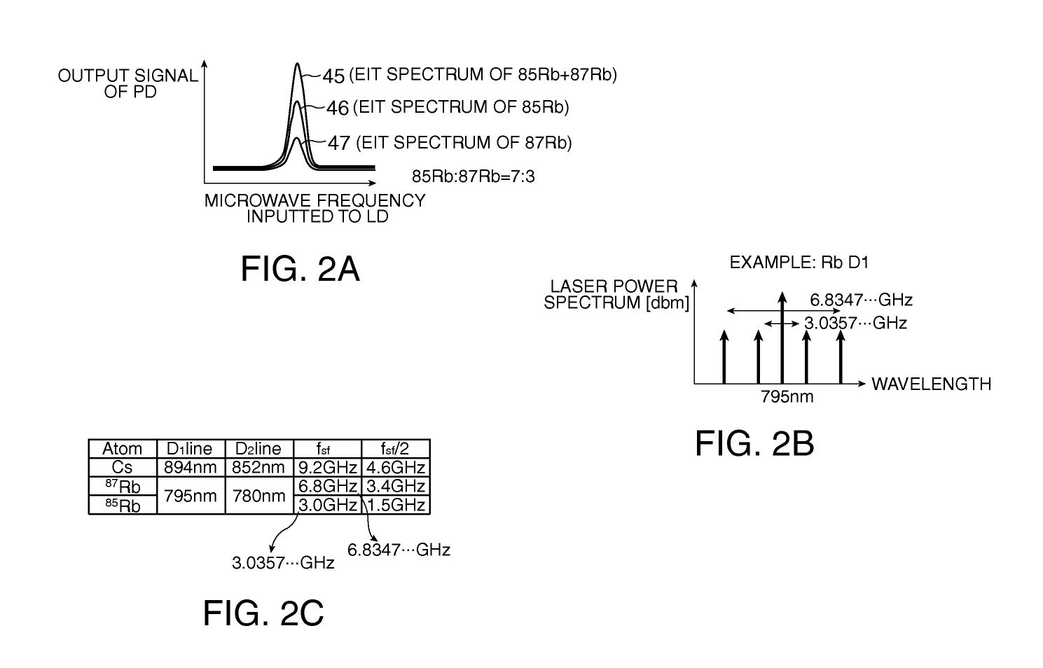

FIGS. 2A to 2C are views for explaining the basic principle of the invention. FIG. 2A is a view showing a relation between an output signal of the PD according to the invention and a frequency of a microwave inputted to the light source. According to an aspect of the invention, it is used that an alkali metal atom has an isotope, and an atomic oscillator is provided in which the level of light absorbed by the photo detector (PD) 3 is raised and the S/N is improved by irradiating a mixture gas of an alkali metal atom and an isotope of the alkali metal atom with plural lights including a first resonant light pair having two frequency components different in frequency and a second resonant light pair having two frequency components different in frequency.

For example, in the case of rubidium, the alkali metal atom is rubidium (85Rb) having a mass number of 85, and the isotope of the alkali metal atom is rubidium (87Rb) having a mass number of 87. It is known that rubidium has 24 kinds of isotopes. Naturally existing rubidium has two kinds of isotopes, that is, a stable isotope 85Rb at a natural existing ratio of 72.2% and a radioactive isotope 87Rb at 27.8%. The relation of the output signal level of the photo detector (PD) 3 at the center frequency at this time is such that an EIT spectrum 47 of 87Rb is lowest, and an EIT spectrum 46 of 85Rb is higher than that. When both are combined, an EIT spectrum 45 can be further increased. Besides, as is apparent from FIGS. 2B and 2C, the center wavelength is 795 nm at D1 line and 780 nm at D2 line, and is common to 85Rb and 87Rb. However, the transition frequency is about 6.8 GHz for 85Rb and is about 3.0 GHz for 87Rb, and two kinds of transition frequencies are obtained. By this, two kinds of side bands can be generated by one laser light, and the number of atoms contributing to the EIT phenomenon can be increased.

FIG. 3 is a block diagram showing a structure of an atomic oscillator of a first embodiment. This atomic oscillator 50 roughly includes a cell 2 containing a mixture gas of alkali metal atoms and isotopes of the alkali metal atoms, a light source (LD) 1 that has coherency and irradiates the gas with plural lights including a first resonant light pair having two frequency components different in frequency and a second resonant light pair having two frequency components different in frequency, a photo detector (PD) 3 to generate a detection signal corresponding to the intensity of light passing through the gas, and a frequency control part 12 that controls, based on the detection signal, a frequency difference of the first resonant light pair to cause an electromagnetically induced transparency phenomenon (hereinafter referred to as an EIT phenomenon) to occur in an alkali metal atom and controls a frequency difference of the second resonant light pair to cause the EIT phenomenon to occur in an isotope of an alkali metal atom.

The frequency control part 12 includes a phase modulation part 7 to phase modulate an output signal of a voltage controlled crystal oscillator 6 by a specified frequency, a first frequency multiplying part 8 to multiply the signal phase-modulated by the phase modulation part 7 to a frequency equal to ½ of a transition frequency of the alkali metal atom, a second frequency multiplying part 9 to multiply the frequency of the signal phase-modulated by the phase modulation part 7 to a frequency equal to ½ of a transition frequency of the isotope of the alkali metal atom, and a mixer to mix the signal multiplied by the first frequency multiplying part 8 and the signal multiplied by the second frequency multiplying part 9. Besides, the synchronous control part 5 includes a low frequency oscillator 17 to oscillate a specified frequency, a phase circuit 16, a multiplier 15 to multiply the signal of the photo detector (PD) 3 and the signal of the phase circuit 16, and a filter 14 to extract a DC component from the output of the multiplier 15.

That is, in order to generate at least four resonant lights (two resonant light pairs), it is conceivable that the resonant light emitted from the light source 1 is modulated to generate side bands, and the frequency spectrum thereof is used. The frequency to modulate the resonant light is required to be equal to ½ of the transition frequency. In this embodiment, the mixture gas of the alkali metal atoms and the isotopes of the alkali metal atoms is sealed in the cell 2, and the frequency control part 12 controls the frequency difference between the frequency components for each of the two resonant light pairs. By this, the resonant light including four frequency components corresponding to the transition frequency of the alkali metal atom and the transition frequency of the isotope of the alkali metal atom can be generated from the resonant light emitted from the light source 1.

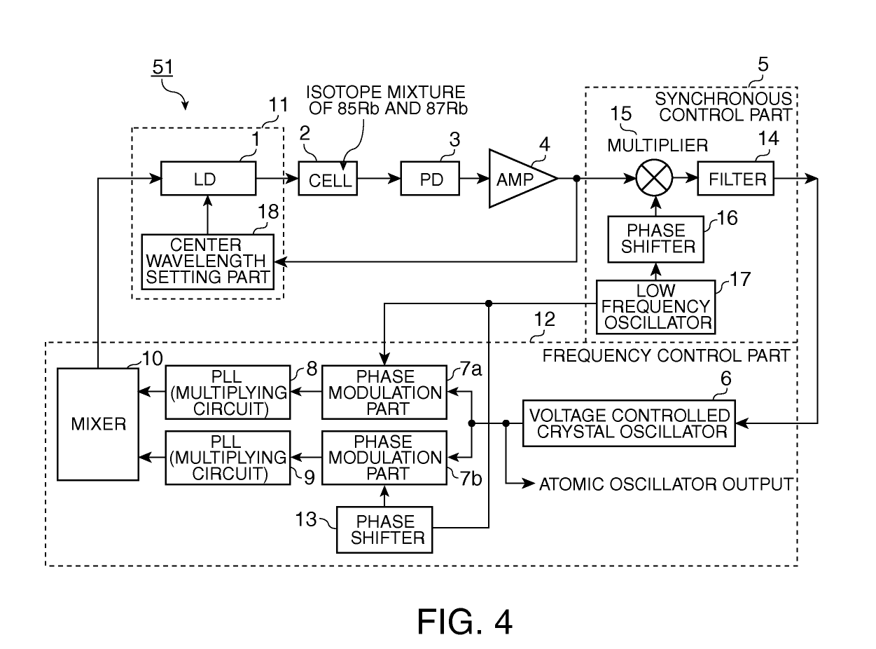

FIG. 4 is a block diagram showing a structure of an atomic oscillator of a second embodiment. The same component is denoted by the same reference numeral as that of FIG. 3 and its explanation is omitted. An atomic oscillator 51 is different from the atomic oscillator 50 of FIG. 3 in that a first frequency multiplying part 8 and a second frequency multiplying part 9 include phase modulation parts 7a and 7b, respectively, and one of the phase modulation parts (7b in FIG. 4) includes a phase shifter 13 to shift a phase. That is, the phase modulation part 7 is commonly used and the two frequency multiplying parts 8 and 9 can be driven. However, there is a possibility that the mutual phases are shifted by a variation in components or the like. Then, when this phenomenon occurs, it is necessary to shift a phase to perform phase alignment. In this embodiment, the phase modulation part 7b includes the phase shifter 13 to shift the phase. By this, the synchronous detection can be accurately and quickly performed.

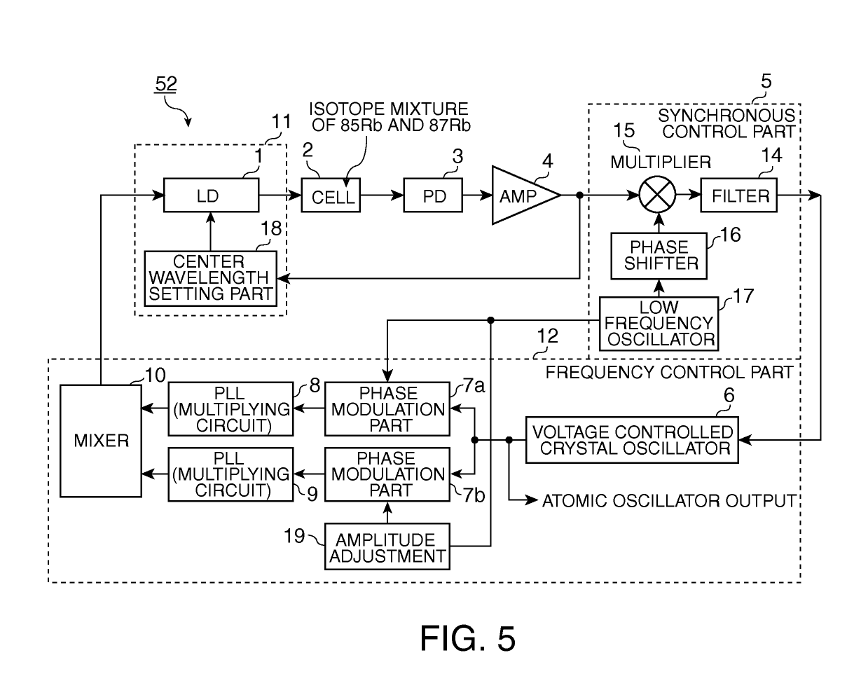

FIG. 5 is a block diagram showing a structure of an atomic oscillator of a third embodiment. The same component is denoted by the same reference numeral as that of FIG. 3 and its explanation is omitted. This atomic oscillator 52 is different from the atomic oscillator 50 of FIG. 3 in that a first frequency multiplying part 8 and a second frequency multiplying part 9 include phase modulation parts 7a and 7b, respectively, and one of the phase modulation parts (7b in FIG. 5) includes an amplitude adjuster 19 to adjust an amplitude of a modulation signal. That is, the phase modulation degree of the outputs of the two frequency multiplying parts 8 and influences the inclination of an error voltage after detection (see FIG. 1C). Accordingly, it is ideally preferable that the phase modulation degrees of the two frequency multiplying parts 8 and 9 are equal to each other. In this embodiment, the phase modulation part 7b includes the amplitude adjuster 19 to adjust the amplitude of the modulation signal. By this, the synchronous detection can be accurately and quickly performed.

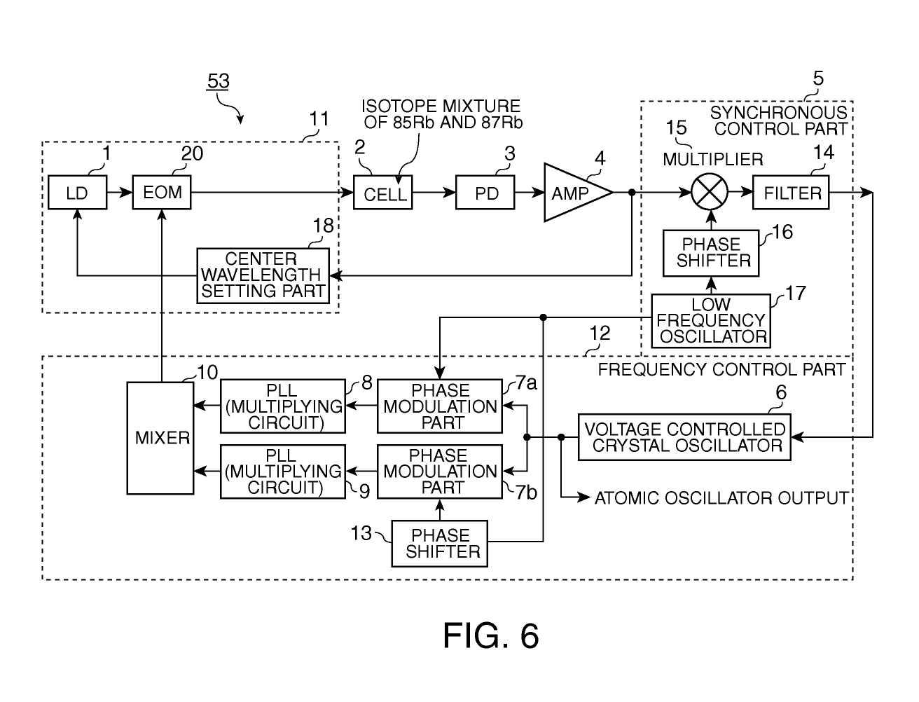

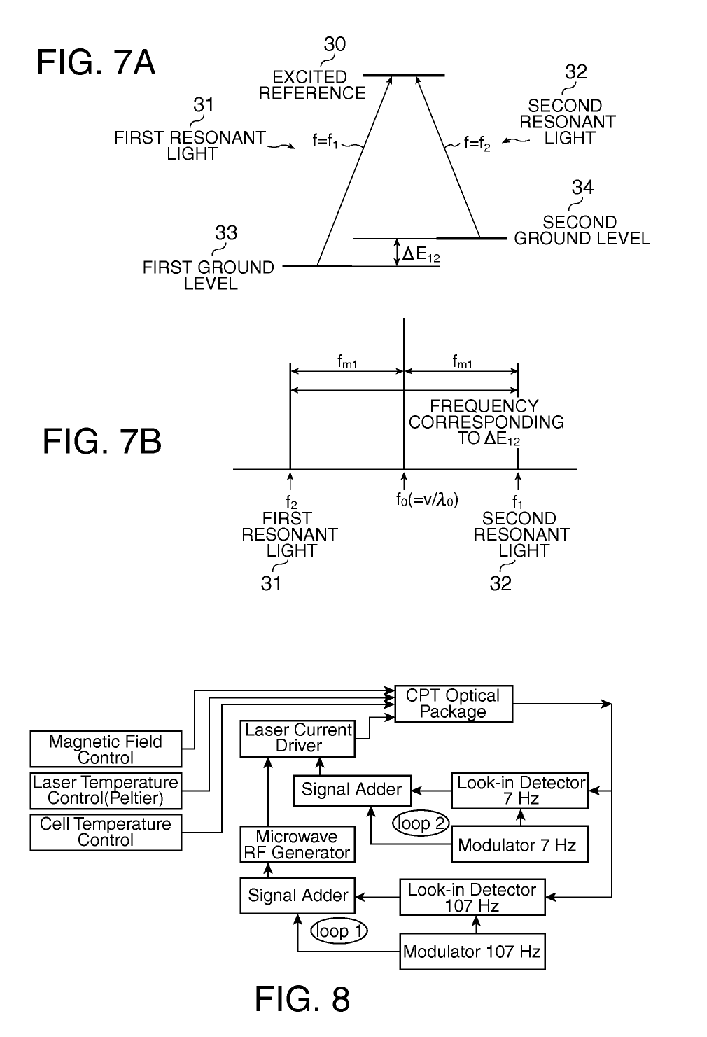

FIG. 6 is a block diagram showing a structure of an atomic oscillator of a fourth embodiment of the invention. The same component is denoted by the same reference numeral as that of FIG. 3 and its explanation is omitted. This atomic oscillator 53 is different from the atomic oscillator 50 of FIG. 3 in that an electro-optical modulator (EOM) 20 to modulate plural lights including a first resonant light pair and a second resonant light pair emitted from a light source 1 is provided. That is, the electro-optical modulator 20 is required in order to modulate the light. However, when the number of frequency spectra is increased, the number of electro-optical modulators 20 must be increased by that, and there is a problem that the cost increases, and the number of parts increases. In this embodiment, an output signal of a first frequency multiplying part 8 and an output signal of a second frequency multiplying part 9 are mixed by a mixer 10, and the one electro-optical modulator 20 is modulated by the output signal. By this, the number of electro-optical modulators 20 is made minimum, and the number of parts can be reduced.

The entire disclosure of Japanese Patent Application No. 2010-140230, filed Jun. 21, 2010 is expressly incorporated by reference herein.

What is claimed is:

1. An atomic oscillator using an electromagnetically induced transparency phenomenon generated by irradiating a resonant light pair to a gaseous metal atom, comprising:
a mixture gas containing the metal atom and an isotope of the metal atom;
a light source that irradiates the mixture gas with lights including a first resonant light pair to cause the electromagnetically induced transparency phenomenon to occur in the metal atom and a second resonant light pair to cause the electromagnetically induced transparency phenomenon to occur in the isotope of the metal atom;
a photo detector that generates a detection signal corresponding to intensity of light passing through the mixture gas; and
a frequency control part that controls a frequency difference of the first resonant light pair and controls a frequency difference of the second resonant light pair based on the detection signal.

2. The atomic oscillator according to claim 1, wherein the frequency control part includes:
a phase modulation part to phase modulate an output signal of a voltage controlled crystal oscillator by a specified frequency;
a first frequency multiplying part to multiply a center frequency of the signal phase-modulated by the phase modulation part to a frequency equal to ½ of a transition frequency of the metal atom;
a second frequency multiplying part to multiply the center frequency of the signal phase-modulated by the phase modulation part to a frequency equal to ½ of a transition frequency of the isotope of the metal atom; and
a mixer to mix the signal multiplied by the first frequency multiplying part and the signal multiplied by the second frequency multiplying part.

3. The atomic oscillator according to claim 2, wherein each of the first frequency multiplying part and the second frequency multiplying part includes the phase modulation part, and one of the phase modulation parts includes a phase shifter to shift a phase.

4. The atomic oscillator according to claim 2, wherein each of the first frequency multiplying part and the second frequency multiplying part includes the phase modulation part, and one of the phase modulation parts includes an amplitude adjuster to adjust an amplitude of a signal.

5. The atomic oscillator according to claim 2, wherein the light source includes an electro-optical modulator.

6. The atomic oscillator according to claim 1, wherein the metal atom is rubidium having a mass number of 85, and the isotope of the metal atom is rubidium having a mass number of 87.
